(19) United States
(12) Patent Application Publication
(10) Pub. No.: US 2022/0005858 A1
(43) Pub. Date: Jan. 6, 2022

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventor: Suguru SAITO, Kanagawa (JP)

(21) Appl. No.: 17/285,752

(22) PCT Filed: Aug. 20, 2019
(86) PCT No.: PCT/JP2019/032430

§ 371 Date: Apr. 15, 2021

(30) Foreign Application Priority Data
Oct. 15, 2018 (JP) 2018-194371

(51) Int. Cl. H01L 27/146; H01L 23/00

(52) U.S. Cl. CPC H01L 27/14634; H01L 27/14645; H01L 27/14621; H01L 27/14627; H01L 27/14636; H01L 2224/80896; H01L 24/08; H01L 24/80; H01L 2224/08145; H01L 2224/80895; H01L 27/1469

(57) ABSTRACT

To provide a solid-state imaging device capable of realizing further improvement in quality and reliability of the solid-state imaging device.

Provided is a solid-state imaging device including a first semiconductor device including an imaging element that generates a pixel signal on a pixel-by-pixel basis, a second semiconductor device in which a first signal processing circuit required for signal processing of the pixel signal is embedded by an embedding member, a third semiconductor device in which a second signal processing circuit required for signal processing of the pixel signal is embedded by an embedding member, and a silicon containing layer, in which the first semiconductor device and the second semiconductor device are electrically connected to each other, the first semiconductor device and the third semiconductor device are electrically connected to each other, the first semiconductor device, the silicon containing layer, and the second semiconductor device are arranged in this order, and the first semiconductor device, the silicon containing layer, and the third semiconductor device are arranged in this order.

### TECHNICAL FIELD

The present technology relates to a solid-state imaging device and an electronic device.

### BACKGROUND ART

In general, a solid-state imaging device such as a complementary metal oxide semiconductor (CMOS) image sensor and a charge coupled device (CCD) is widely used in a digital still camera, a digital video camera and the like.

In recent years, a technology for downsizing a solid-state imaging device has been actively developed, and, for example, a technology of stacking a solid-state imaging element and a circuit such as a signal processing circuit and a memory circuit by wafer on wafer (WoW) to join in a wafer state is proposed.

### CITATION LIST

### Patent Document

Patent Document 1: Japanese Patent Application Laid-Open No. 2014-099582

### SUMMARY OF THE INVENTION

### Problems to be Solved by the Invention

However, although the technology proposed in Patent Document 1 might achieve downsizing of the solid-state imaging device, there is a risk that further improvement in quality and reliability of the solid-state imaging device cannot be realized.

Therefore, the present technology has been made in view of such a situation, and a principal object thereof is to provide a solid-state imaging device capable of realizing further improvement in quality and reliability of the solid-state imaging device, and an electronic device equipped with the solid-state imaging device.

### Solutions to Problems

As a result of diligent research to solve the above-described object, the present inventors have succeeded in further improving the quality and reliability of the solid-state imaging device, and have completed the present technology.

That is, as a first aspect, the present technology provides a solid-state imaging device provided with:

a first semiconductor device including an imaging element that generates a pixel signal on a pixel-by-pixel basis;

a second semiconductor device in which a signal processing circuit required for signal processing of the pixel signal is embedded by an embedding member; and

a silicon containing layer,

in which the first semiconductor device and the second semiconductor device are electrically connected to each other, and

the first semiconductor device, the silicon containing layer, and the second semiconductor device are arranged in this order.

In the solid-state imaging device of the first aspect according to the present technology, a through via that penetrates through the silicon containing layer may be formed, and the first semiconductor device and the second semiconductor device may be electrically connected to each other via the through via.

In the solid-state imaging device of the first aspect according the present technology, the first semiconductor device and the second semiconductor device may be electrically connected to each other by Cu—Cu joint.

In the solid-state imaging device of the first aspect according to the present technology, the first semiconductor device and the second semiconductor device may be electrically connected to each other by Cu—Cu joint, and

the silicon containing layer may be formed at an interface of the Cu—Cu joint between the first semiconductor device and the second semiconductor device.

In the solid-state imaging device of the first aspect according to the present technology, a through via that penetrates through the silicon containing layer may be formed, and the first semiconductor device and the second semiconductor device may be electrically connected to each other by Cu—Cu joint via the through via.

In the solid-state imaging device of the first aspect according to the present technology, the silicon containing layer may be continuously formed across a plurality of the pixels.

In the solid-state imaging device of the first aspect according to the present technology, the silicon containing layer may contain at least one type of silicon selected from a group consisting of single crystal silicon, amorphous silicon, and polycrystalline silicon.

In the solid-state imaging device of the first aspect according to the present technology, the silicon containing layer may contain dopant, and a content of the dopant in the silicon containing layer may be 1E18 atoms/cm³ or more.

Furthermore, as a second aspect, the present technology provides a solid-state imaging device provided with:

a first semiconductor device including an imaging element that generates a pixel signal on a pixel-by-pixel basis;

a second semiconductor device in which a first signal processing circuit required for signal processing of the pixel signal is embedded by an embedding member;

a third semiconductor device in which a second signal processing circuit required for signal processing of the pixel signal is embedded by an embedding member; and

a silicon containing layer,

in which the first semiconductor device and the second semiconductor device are electrically connected to each other,

the first semiconductor device and the third semiconductor device are electrically connected to each other,

the first semiconductor device, the silicon containing layer, and the second semiconductor device are arranged in this order, and

the first semiconductor device, the silicon containing layer, and the third semiconductor device are arranged in this order.

In the solid-state imaging device of the second aspect according the present technology, the second semiconductor device and the third semiconductor device may be formed in substantially the same layer.

In the solid-state imaging device of the second aspect according to the present technology, a first through via and a second through via that penetrate through the silicon containing layer may be formed,

the first semiconductor device and the second semiconductor device may be electrically connected to each other via the first through via, and

the first semiconductor device and the third semiconductor device may be electrically connected to each other via the second through via.

In the solid-state imaging device of the second aspect according to the present technology, the first semiconductor device and the second semiconductor device may be electrically connected to each other by Cu—Cu joint, and

the first semiconductor device and the third semiconductor device may be electrically connected to each other by Cu—Cu joint.

In the solid-state imaging device of the second aspect according to the present technology, the first semiconductor device and the second semiconductor device may be electrically connected to each other by Cu—Cu joint,

the first semiconductor device and the third semiconductor device may be electrically connected to each other by Cu—Cu joint, and

the silicon containing layer may be formed at an interface of the Cu—Cu joint between the first semiconductor device and the second and third semiconductor devices.

In the solid-state imaging device of the second aspect according to the present technology, a first through via and a second through via that penetrate through the silicon containing layer may be formed,

the first semiconductor device and the second semiconductor device may be electrically connected to each other by Cu—Cu joint via the first through via, and

the first semiconductor device and the third semiconductor device may be electrically connected to each other by Cu—Cu joint via the second through via.

In the solid-state imaging device of the second aspect according to the present technology, the silicon containing layer may be continuously formed across a plurality of the pixels.

In the solid-state imaging device of the second aspect according to the present technology, the silicon containing layer may contain at least one type of silicon selected from a group consisting of single crystal silicon, amorphous silicon, and polycrystalline silicon.

In the solid-state imaging device of the second aspect according to the present technology, the silicon containing layer may contain dopant, and a content of the dopant in the silicon containing layer may be 1E18 atoms/cm³ or more.

Moreover, as a third aspect, the present technology provides

an electronic device equipped with a solid-state imaging device,

the solid-state imaging device provided with:

a first semiconductor device including an imaging element that generates a pixel signal on a pixel-by-pixel basis;

a second semiconductor device in which a signal processing circuit required for signal processing of the pixel signal is embedded by an embedding member; and

a silicon containing layer,

in which the first semiconductor device and the second semiconductor device are electrically connected to each other, and

the first semiconductor device, the silicon containing layer, and the second semiconductor device are arranged in this order,

as a fourth aspect, the present technology provides an electronic device equipped with a solid-state imaging device,

the solid-state imaging device provided with:

a first semiconductor device including an imaging element that generates a pixel signal on a pixel-by-pixel basis;

a second semiconductor device in which a first signal processing circuit required for signal processing of the pixel signal is embedded by an embedding member;

a third semiconductor device in which a second signal processing circuit required for signal processing of the pixel signal is embedded by an embedding member; and

a silicon containing layer,

in which the first semiconductor device and the second semiconductor device are electrically connected to each other,

the first semiconductor device and the third semiconductor device are electrically connected to each other,

the first semiconductor device, the silicon containing layer, and the second semiconductor device are arranged in this order, and

the first semiconductor device, the silicon containing layer, and the third semiconductor device are arranged in this order, and

moreover, as a fifth aspect, the present technology provides an electronic device equipped with a solid-state imaging device according to the present technology.

According to the present technology, it is possible to realize further improvement in quality and reliability of the solid-state imaging device. Note that, the effects herein described are not necessarily limited and may be any of the effects described in the present disclosure.

### BRIEF DESCRIPTION OF DRAWINGS

FIG. 1 is a view illustrating a configuration example of a solid-state imaging device to which the present technology is applied.

FIG. 2 is a view for illustrating a manufacturing method of the solid-state imaging device to which the present technology is applied.

FIG. 3 is a view for illustrating a manufacturing method of the solid-state imaging device to which the present technology is applied.

FIG. 4 is a view illustrating a configuration example of the solid-state imaging device to which the present technology is applied.

FIG. 5 is a view illustrating a configuration example of a solid-state imaging device to which the present technology is applied.

FIG. 6 is a view for illustrating a manufacturing method of the solid-state imaging device to which the present technology is applied.

FIG. 7 is a view for illustrating a manufacturing method of the solid-state imaging device to which the present technology is applied.

FIG. 8 is a view illustrating a configuration example of a solid-state imaging device.

FIG. 9 is a view illustrating a usage example of a solid-state imaging device according to first to third embodiments to which the present technology is applied.

FIG. 10 is a functional block diagram of an example of an electronic device according to a fourth embodiment to which the present technology is applied.

FIG. 11 is a view illustrating an example of a schematic configuration of an endoscopic surgery system.

FIG. 12 is a block diagram illustrating an example of a functional configuration of a camera head and a CCU.

FIG. 13 is a block diagram illustrating an example of a schematic configuration of a vehicle control system.

FIG. 14 is an illustrative view illustrating an example of an installation position of a vehicle exterior information detection unit and an imaging unit.

### MODE FOR CARRYING OUT THE INVENTION

Hereinafter, a preferred mode for carrying out the present technology is described. An embodiment hereinafter described illustrates an example of a representative embodiment of the present technology, and the scope of the present technology is not narrowed by this. Note that, unless otherwise specified, in the drawings, “upper” means an upward direction or an upper side in the drawing, “lower” means a downward direction or a lower side in the drawing, “left” means a leftward direction or a left side in the drawing, and “right” means a rightward direction or a right side in the drawing. Furthermore, in the drawings, the same or equivalent elements or members are assigned with the same reference numeral, and the description thereof is not repeated.

The description is given in the following order.

1. Outline of Present Technology

2. First Embodiment (Example 1 of Solid-State Imaging Device)

3. Second Embodiment (Example 2 of Solid-State Imaging Device)

4. Third Embodiment (Example 3 of Solid-State Imaging Device)

5. Fourth Embodiment (Example of Electronic Device)

6. Usage Example of Solid-State Imaging Device to which Present Technology is applied

7. Application Example to Endoscopic Surgery System

8. Application Example to Mobile Body

### 1. Outline of Present Technology

First, an outline of the present technology is described.

There is a solid-state imaging device having a device structure of dicing an image sensor and ICs such as a logic (signal processing IC) and a memory, arranging only non-defective chips, making the same a wafer, forming wiring, and adhering the same to an image sensor (CIS) to connect. As compared to wafer on wafer (WoW), a yield loss and an area loss are small, and a connection electrode may be miniaturized as compared to that in bump connection.

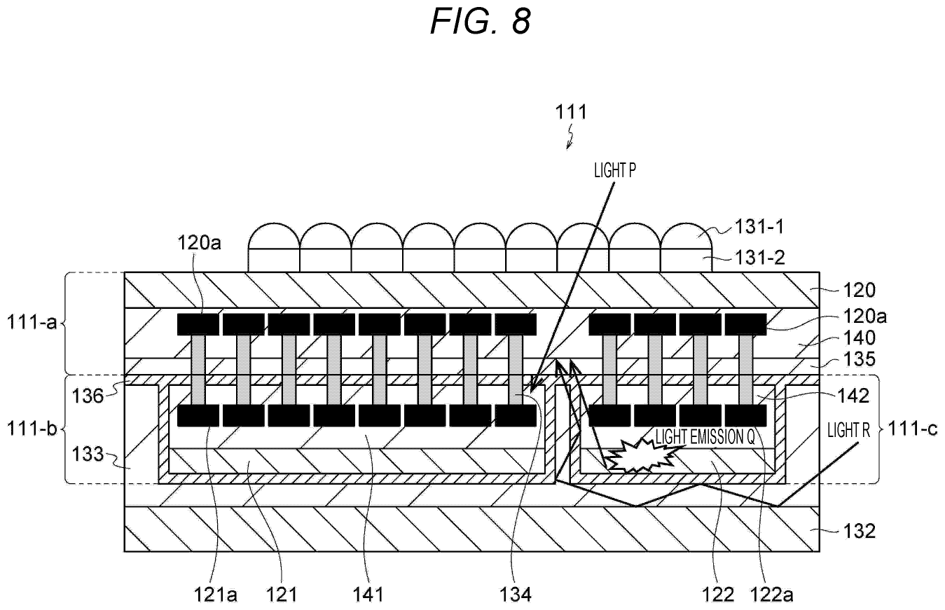

The above-described solid-state imaging device is described with reference to FIG. 8. FIG. 8 is a cross-sectional view of a solid-state imaging device 111.

In the solid-state imaging device 111 illustrated in FIG. 8, an on-chip lens 131-1, an on-chip color filter 131-2, a solid-state imaging element 120, a wiring layer 140, and an oxide film 135 are stacked in this order from an upper side (light incident side) in FIG. 8, and below them (lower side in FIG. 8), for example, a memory circuit 121 and a logic circuit 122 are stacked in the same layer as signal processing circuits. The memory circuit 121 is arranged on a left side (left side in FIG. 8), and the logic circuit 122 is arranged on a right side (right side in FIG. 8). Then, in the solid-state imaging device 111 illustrated in FIG. 8, a support substrate 132 is formed below the memory circuit 121 and the logic circuit 122 (lower side in FIG. 8).

That is, as illustrated in FIG. 8, the solid-state imaging device 111 includes a first semiconductor device 111-a including the solid-state imaging element 120, the wiring layer 140, and the oxide film 135, a second semiconductor device 111-b including a memory circuit 121, a wiring layer 141, and an oxide film 136, and a third semiconductor device 111-c including a logic circuit 122, a wiring layer 142, and the oxide film 136.

Out of terminals 120a formed in the wiring layer 140 of the solid-state imaging element 120, a terminal 120a on the memory circuit 121 is electrically connected to a terminal 121a formed in the wiring layer 141 of the memory circuit 121 by wiring 134 connected by Cu—Cu joint.

Furthermore, out of the terminals 120a formed in the wiring layer 140 of the solid-state imaging element 120, a terminal 120a on the logic circuit 122 is electrically connected to a terminal 122a formed in the wiring layer 142 of the logic circuit 122 by wiring 134 connected by Cu—Cu joint.

A space around the second semiconductor device 111-b and the third semiconductor device 111-c in the second semiconductor device 111-b in which the memory circuit 121 and the wiring layer 141 are formed and the third semiconductor device 111-c in which the logic circuit 122 and the wiring layer 142 are formed is filled with an oxide film 133. Therefore, the second semiconductor device 111-b and the third semiconductor device 111-c are in a state of being embedded in the oxide film (insulating film) 133.

Furthermore, on a boundary between the first semiconductor device 111-a and the second and third semiconductor devices 111-b and 111-c, the oxide film 135 and the oxide film 136 are formed in this order from the upper side (light incident side) in FIG. 8.

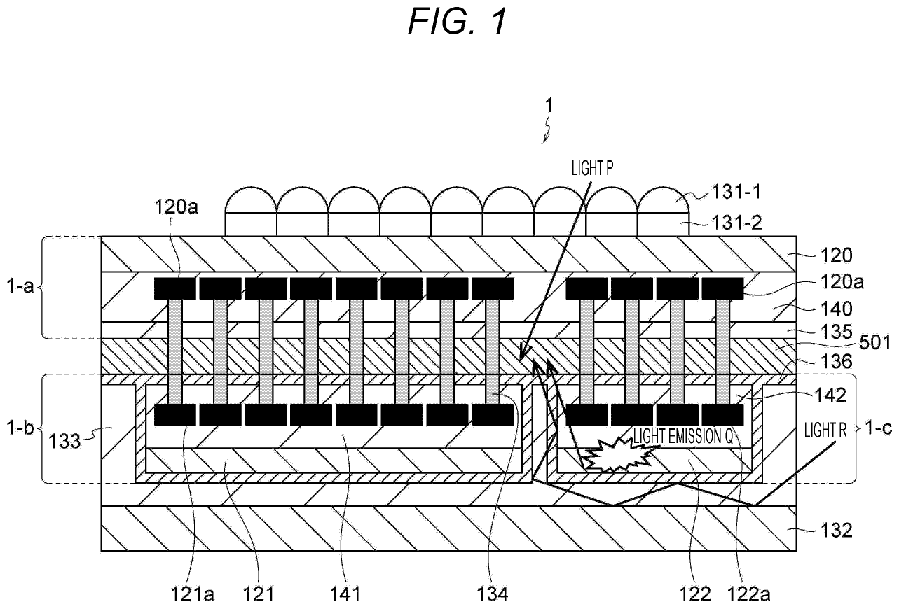

Moreover, the second and third semiconductor devices 111-b and 111-c are joined to the support substrate 132 via the oxide film 133 and an oxide film (not illustrated in FIG. 1; an oxide film between the oxide film 133 and the support substrate 132).

However, in the solid-state imaging device 111, when a space between the third semiconductor device (for example, a logic chip) and the second semiconductor device (for example, a memory chip) is filled with an insulating film (oxide film and the like) (the oxide film 133 in FIG. 8) to flatten, at the time of thermal treatment in a manufacturing process, variation in film thickness of a silicon (Si) substrate on which a photodiode (PD) is formed forming the solid-state imaging element might occur due to a difference in thermal expansion between materials used when manufacturing the solid-state imaging device, for example, an insulating material used as an embedding material and a metal material (Cu, Al) used as wiring and might affect a final imaging characteristic. Furthermore, an effect of hot carrier light emission (HC light emission) (light emission Q in FIG. 8) occurring on a chip end face and a transistor forming a logic substrate, light from outside (light R in FIG. 8), and light leaking in from incident light transmitted through the image sensor (light P in FIG. 8) might change due to presence or absence of a chip to affect the imaging characteristic.

The present technology is achieved in view of the above circumstances. A solid-state imaging device as a first aspect according to the present technology is a solid-state imaging device provided with a first semiconductor device including an imaging element that generates a pixel signal on a pixel-by-pixel basis, a second semiconductor device in which a signal processing circuit required for signal processing of the pixel signal is embedded by an embedding member, and a silicon containing layer, in which the first semiconductor device and the second semiconductor device are electrically connected to each other, and the first semiconductor device, the silicon containing layer, and the second semiconductor device are arranged in this order.

Furthermore, a solid-state imaging device as a second aspect according to the present technology is a solid-state imaging device provided with a first semiconductor device including an imaging element that generates a pixel signal on a pixel-by-pixel basis, a second semiconductor device in which a first signal processing circuit required for signal processing of the pixel signal is embedded by an embedding member, a third semiconductor device in which a second signal processing circuit required for signal processing of the pixel signal is embedded by an embedding member, and a silicon containing layer, in which the first semiconductor device and the second semiconductor device are electrically connected to each other, the first semiconductor device and the third semiconductor device are electrically connected to each other, the first semiconductor device, the silicon containing layer, and the second semiconductor device are arranged in this order, and the first semiconductor device, the silicon containing layer, and the third semiconductor device are arranged in this order.

Note that the solid-state imaging device according to the present technology is not limited to the first and second aspects, and may include three or more semiconductor devices in which the signal processing circuit required for the signal processing of the pixel signal is embedded by the embedding member. Furthermore, the silicon (Si) containing layer may contain an element other than silicon (Si), for example, germanium (Ge) and the like. Moreover, the silicon (Si) containing layer may be a silicon containing substrate.

In an example of the solid-state imaging device according to the present technology, a silicon (Si) layer is interposed at a Cu—Cu joint interface between a chip (a chip forming a second semiconductor device or a chip forming a second semiconductor device and a third semiconductor device) and a wafer (a chip forming a first semiconductor device), the silicon (Si) layer is not divided in a field angle of an image sensor but continuously formed across a plurality of pixels, a through via is formed to penetrate through the silicon (Si) layer, and the through via is joined by Cu—Cu joint to a chip side.

According to the present technology, it is possible to realize further improvement in quality and reliability of the solid-state imaging device. Specifically, according to the present technology, as for the silicon (Si) containing layer, by introducing the silicon (Si) containing layer between a chip (for example, a chip forming the second semiconductor device or a chip forming the second semiconductor device and the third semiconductor device) and a wafer (a chip forming the first semiconductor device), rigidity increases, and for example, a thrust toward a photodiode (PD) side due to a difference in thermal expansion between an embedding material (insulating material) and wiring (metal material) decreases, an effect on an imaging characteristic decreases, and the silicon (Si) layer may absorb light from outside, hot carrier light emission (HC light emission) from a logic substrate (logic circuit), leaking-in incident light and the like to decrease the effect on the imaging characteristic. Moreover, according to the present technology, electromagnetic noise between upper and lower substrates may be blocked by introducing a heavily doped silicon (Si) layer.

Hereinafter, embodiments according to the present technology are described in detail.

### 2. First Embodiment (Example 1 of Solid-State Device)

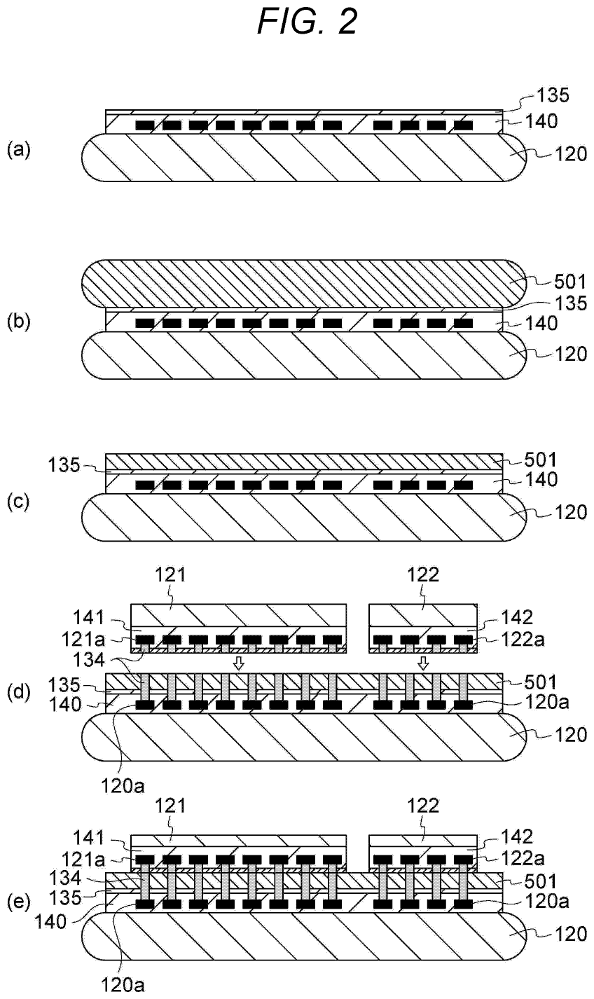

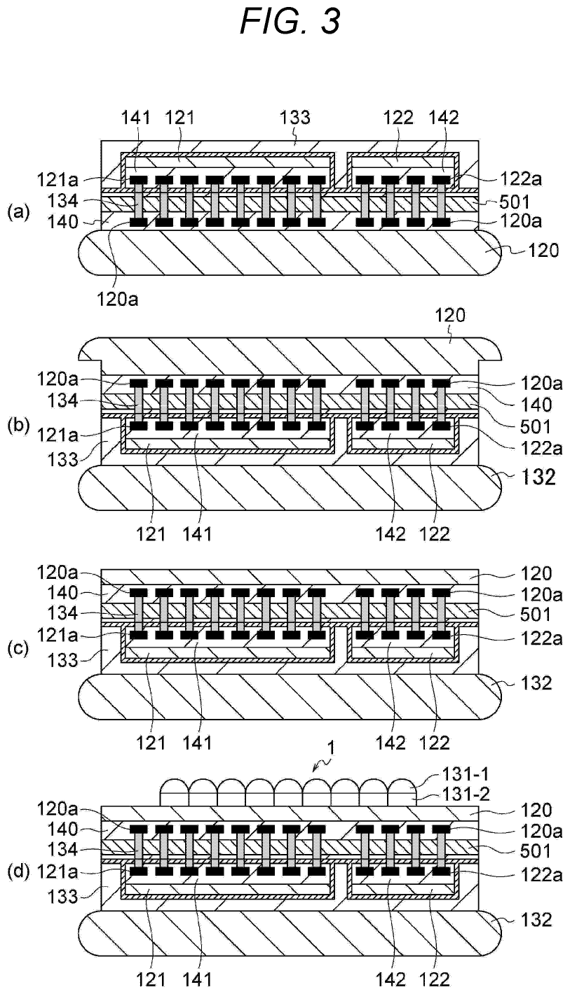

A solid-state imaging device of a first embodiment (example 1 of a solid-state imaging device) according to the present technology is described with reference to FIGS. 1 to 3. FIG. 1 is a cross-sectional view of a solid-state imaging device 1 of the first embodiment according to the present technology, and FIGS. 2 and 3 are cross-sectional views for illustrating a manufacturing method of the solid-state imaging device 1 of the first embodiment according to the present technology.

In the solid-state imaging device 1 illustrated in FIG. 1, an on-chip lens 131-1, an on-chip color filter 131-2, a solid-state imaging element 120, a wiring layer 140, an oxide film 135, and a silicon (Si) layer 501 are stacked in this order from an upper side (light incident side) in FIG. 1, and below them (lower side in FIG. 1), for example, a memory circuit 121 and a logic circuit 122 are stacked in substantially the same layer as signal processing circuits. The memory circuit 121 is arranged on a left side (left side in FIG. 1), and the logic circuit 122 is arranged on a right side (right side in FIG. 1). Then, in the solid-state imaging device 1 illustrated in FIG. 1, a support substrate 132 is formed below the memory circuit 121 and the logic circuit 122 (lower side in FIG. 1).

That is, as illustrated in FIG. 1, the solid-state imaging device 1 includes a first semiconductor device 1-a including the solid-state imaging element 120, the wiring layer 140, and the oxide film 135, a second semiconductor device 1-b including the memory circuit 121, a wiring layer 141, and an oxide film 136, and a third semiconductor device 1-c including the logic circuit 122, a wiring layer 142, and the oxide film 136, and a silicon containing layer (the silicon (Si) layer 501 in the first embodiment) is arranged (stacked) between the first semiconductor device 1-a and the second and third semiconductor devices 1-b and 1-c.

The silicon (Si) layer 501 may also have a structure not divided in a field angle of the solid-state imaging element 120 (image sensor) but continuously formed across a plurality of pixels. A thickness of the silicon (Si) layer 501 may be any thickness, but is preferably 3 μm or more so that visible light may be absorbed. Furthermore, a relationship between the thickness of the silicon (Si) layer 501 (thickness A) and a thickness of the solid-state imaging element 120 (silicon (Si) substrate) (thickness B) preferably satisfies a relational expression A≥B. Note that the silicon (Si) layer may also be a silicon (Si) substrate.

As illustrated in FIG. 1, the silicon (Si) layer absorbs hot carrier light emission (HC light emission) (light emission Q in FIG. 1) occurring on a chip end face and a transistor forming a logic substrate, light from outside (light R in FIG. 1), and light leaking in from incident light transmitted through the image sensor (light P in FIG. 1).

Out of terminals 120a formed in the wiring layer 140 of the solid-state imaging element 120, a terminal 120a on the memory circuit 121 is electrically connected to a terminal 121a formed in the wiring layer 141 of the memory circuit 121 by wiring 134 connected by Cu—Cu joint and including a through via that penetrates through the silicon layer (Si) layer 501.

Furthermore, out of terminals 120a formed in the wiring layer 140 of the solid-state imaging element 120, a terminal 120a on the logic circuit 122 is electrically connected to a terminal 122a formed in the wiring layer 142 of the logic circuit 122 by wiring 134 connected by Cu—Cu joint and including a through via that penetrates through the silicon layer (Si) layer 501.

A space around the semiconductor device 1-b and the semiconductor device 1-c in the second semiconductor device 1-b in which the memory circuit 121 and the wiring layer 141 are formed and the third semiconductor device 1-c in which the logic circuit 122 and the wiring layer 142 are formed is filled with an oxide film 133. Therefore, the semiconductor device 1-b and the semiconductor device 1-c are in a state of being embedded in the oxide film (insulating film) 133.

Furthermore, in a boundary region between the first semiconductor device 1-a and the second and third semiconductor devices 1-b and 1-c, the oxide film 135, the silicon (Si) layer 501, and the oxide film 136 are formed in this order from an upper side (light incident side) in FIG. 1. That is, the silicon (Si) layer 501 is formed at an interface of the Cu—Cu joint between the first semiconductor device 1-a and the second and third semiconductor devices 1-b and 1-c.

Moreover, the second and third semiconductor devices 1-b and 1-c are joined to the support substrate 132 via the oxide film 133 and an oxide film (not illustrated in FIG. 1; an oxide film between the oxide film 133 and the support substrate 132).

Next, a manufacturing method of the solid-state imaging device 1 is described with reference to FIGS. 2 and 3.

As illustrated in FIG. 2(a), in a back end of line (BEOL) process, the wiring layer 140 is formed on the solid-state imaging element (image sensor substrate) 120 and the oxide film 135 is formed on the wiring layer 140 to manufacture a first semiconductor device (the same as the first semiconductor device 1-a in FIG. 1).

The silicon (Si) layer (this may be a silicon (Si) substrate) 501 is adhered onto the first semiconductor device (oxide film 135) (FIG. 2(b)).

Next, as illustrated in FIG. 2(c), the silicon (Si) layer (silicon (Si) substrate) 501 is thinned.

For the Cu—Cu joint, the wiring 134 including the through via that penetrates through the silicon (Si) layer (silicon (Si) substrate) 501 is formed for the terminal 120a, and as illustrated in FIG. 2(d), the first semiconductor device including the solid-state imaging element 120 and the like and diced second semiconductor device (memory chip) (the same as the second semiconductor device 1-b in FIG. 1) and third semiconductor device (logic chip) (the same as the third semiconductor device 1-c in FIG. 1) are joined by Cu—Cu joint by the wiring 134 by chip on wafer (CoW) to be electrically connected to each other. Note that, the terminal 121a and the wiring 134 connected to the terminal 121a are formed in advance in the second semiconductor device (memory chip), and the terminal 122a and the wiring 134 connected to the terminal 122a are formed in the third semiconductor device (logic chip).

As illustrated in FIG. 2(e), a silicon (Si) substrate forming the memory circuit 121 of the second semiconductor device (memory chip) and a silicon (Si) substrate forming the logic circuit 122 of the third semiconductor device (logic chip) are thinned.

This is described with reference to FIG. 3.

As illustrated in FIG. 3(a), a step in the second semiconductor device (memory chip) and the third semiconductor device (logic chip) is embedded and flattened. An inorganic material may be used, an organic material may be used, or a combination of both of them may be used for embedding and flattening the chip step. In FIG. 3(a), an embedding member is the oxide film (insulating film) 133.

As illustrated in FIG. 3(b), it is inverted such that the solid-state imaging element 120 in a lower portion illustrated in FIG. 3(a) (lower side in FIG. 3(a)) is located in an upper portion (upper side in FIG. 3(b)), the support substrate 132 is adhered to a lower portion of the oxide film 133 (lower side in FIG. 3(b)) via an oxide film (insulating film; not illustrated), and the silicon (Si) substrate forming the solid-state imaging element 120 is thinned to a predetermined thickness (FIG. 3(c)).

Finally, as illustrated in FIG. 3(d), a back surface light-shielding structure (not illustrated) is formed, the on-chip color filter 131-2 is formed on the solid-state imaging element 120, and the on-chip lens 131-1 is formed on the on-chip color filter 131-2. Then, by opening a pad (not illustrated), a device structure of the solid-state imaging device 1 is completed, and the solid-state imaging device 1 is manufactured.

According to the solid-state imaging device 1 of the first embodiment according to the present technology, it is possible to realize further improvement in quality and reliability of the solid-state imaging device. Specifically, according to the solid-state imaging device 1 of the first embodiment according to the present technology, as for the silicon (Si) layer 501, by introducing the silicon (Si) layer 501 between a chip (for example, a chip forming the second semiconductor device 1-b or a chip forming the second semiconductor device 1-b and the third semiconductor device 1-c) and a wafer (chip forming the first semiconductor device 1-a), rigidity increases, and for example, a thrust toward a photodiode (PD) side due to a difference in thermal expansion between an embedding material (insulating material) and wiring (metal material) decreases, an effect on an imaging characteristic decreases, and the silicon (Si) layer 501 may absorb the light from outside, the hot carrier light emission (HC light emission) from the logic substrate (logic circuit), the leaking-in incident light and the like to decrease the effect on the imaging characteristic.

### 3. Second Embodiment (Example 2 of Solid-State Imaging Device)

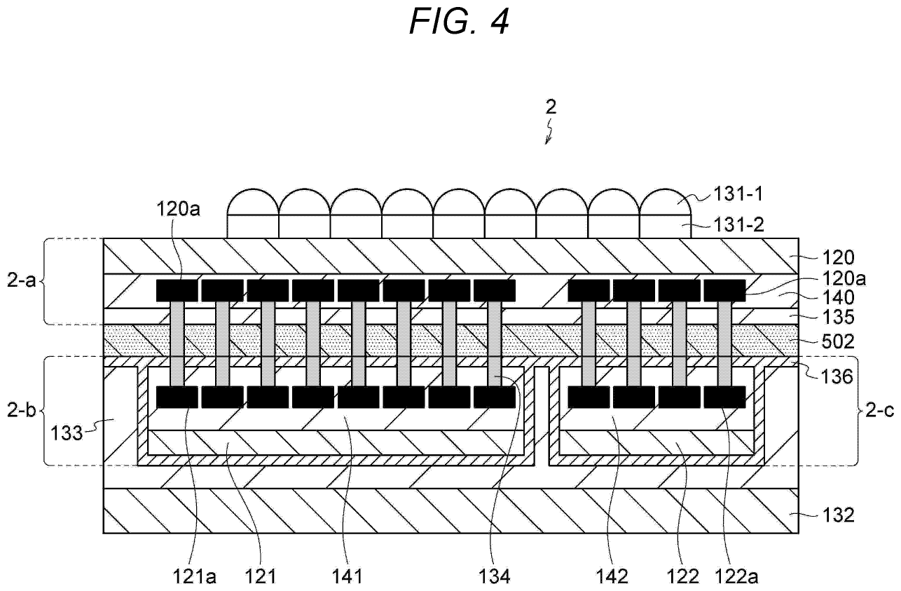

A solid-state imaging device of a first embodiment (example 1 of the solid-state imaging device) according to the present technology is described with reference to FIG. 4. FIG. 4 is a cross-sectional view of a solid-state imaging device 2 of the second embodiment according to the present technology.

In the solid-state imaging device 2 illustrated in FIG. 4, an on-chip lens 131-1, an on-chip color filter 131-2, a solid-state imaging element 120, a wiring layer 140, an oxide film 135, and a silicon (Si) layer 502 containing a high level of dopant are stacked in this order from an upper side (light incident side) in FIG. 4, and below them (lower side in FIG. 4), for example, a memory circuit 121 and a logic circuit 122 are stacked in substantially the same layer as signal processing circuits. The memory circuit 121 is arranged on a left side (left side in FIG. 4), and the logic circuit 122 is arranged on a right side (right side in FIG. 4). Then, in the solid-state imaging device 2 illustrated in FIG. 4, a support substrate 132 is formed below the memory circuit 121 and the logic circuit 122 (lower side in FIG. 4).

That is, as illustrated in FIG. 4, the solid-state imaging device 2 includes a first semiconductor device 2-a including the solid-state imaging element 120, the wiring layer 140, and the oxide film 135, a second semiconductor device 2-b including the memory circuit 121, a wiring layer 141, and an oxide film 136, and a third semiconductor device 2-c including the logic circuit 122, a wiring layer 142, and an oxide film 136, and a silicon containing layer (silicon (Si) layer 502 containing a high level of dopant in the second embodiment) is arranged (stacked) between the first semiconductor device 2-a and the second and third semiconductor devices 2-b and 2-c.

The silicon (Si) layer 502 containing a high level of dopant may also have a structure not divided in a field angle of the solid-state imaging element 120 (image sensor) but continuously formed across a plurality of pixels. A thickness of the silicon (Si) layer 502 may be any thickness, but is preferably 3 μm or more so that visible light may be absorbed. Furthermore, a relationship between the thickness of the silicon (Si) layer 502 containing a high level of dopant (thickness A) and a thickness of the solid-state imaging element 120 (silicon (Si) substrate) (thickness B) preferably satisfies a relational expression A≥B. Note that the silicon (Si) layer 502 containing a high level of dopant may also be a silicon (Si) substrate containing a high level of dopant.

The silicon (Si) layer 502 containing a high level of dopant has a heavily doped structure (for example, containing dopant of 1E18 atoms/cm³ or more). The silicon (Si) layer 502 containing a high level of dopant may behave like metal, and as a result, this has a function of blocking electromagnetic noise between upper and lower substrates (a silicon (Si) substrate forming the first semiconductor device 2-a, and a silicon (Si) substrate forming the second semiconductor device 2-b and a silicon (Si) substrate forming the third semiconductor device) in FIG. 2. The dopant is, for example, boron (B), phosphorus (P), arsenic (As) and the like.

Although not illustrated in FIG. 2, as is the case with the solid-state imaging device 1 in the first embodiment, the silicon (Si) layer 502 containing a high level of dopant may absorb hot carrier light emission (HC light emission) occurring on a chip end face and a transistor forming a logic substrate, light from outside, and light leaking in from incident light transmitted through the solid-state imaging element (image sensor) 120.

Out of terminals 120a formed in the wiring layer 140 of the solid-state imaging element 120, a terminal 120a on the memory circuit 121 is electrically connected to a terminal 121a formed in the wiring layer 141 of the memory circuit 121 by wiring 134 connected by Cu—Cu joint and including a through via that penetrates through the silicon (Si) layer 502 containing a high level of dopant.

Furthermore, out of the terminals 120a formed in the wiring layer 140 of the solid-state imaging element 120, a terminal 120a on the logic circuit 122 is electrically connected to a terminal 122a formed in the wiring layer 142 of the logic circuit 122 by wiring 134 connected by Cu—Cu joint and including a through via that penetrates through the silicon layer (Si) layer 502 containing a high level of dopant.

A space around the semiconductor device 2-b and the semiconductor device 2-c in the second semiconductor device 2-b in which the memory circuit 121 and the wiring layer 141 are formed and the third semiconductor device 2-c in which the logic circuit 122 and the wiring layer 142 are formed is filled with an oxide film (insulating film) 133. Therefore, the semiconductor device 2-b and the semiconductor device 2-c are in a state of being embedded in the oxide film (insulating film) 133.

Furthermore, in a boundary region between the first semiconductor device 2-a and the second and third semiconductor devices 2-b and 2-c, the oxide film 135, the silicon (Si) layer 502 containing a high level of dopant, and the oxide film 136 are formed in this order from an upper side (light incident side) in FIG. 4. That is, the silicon (Si) layer 502 containing a high level of dopant is formed at an interface of the Cu—Cu joint between the first semiconductor device 2-a and the second and third semiconductor devices 2-b and 2-c.

Moreover, the second and third semiconductor devices 2-b and 2-c are joined to the support substrate 132 via the oxide film (insulating film) 133 and an oxide film (not illustrated in FIG. 2; an oxide film between the oxide film 133 and the support substrate 132).

In a manufacturing method of the solid-state imaging device 2, contents in FIGS. 2 and 3 described above may be applied as they are with the silicon (Si) layer 501 (this may also be the silicon (Si) substrate) replaced with the silicon (Si) layer 502 containing a high level of dopant (this may also be the silicon (Si) substrate containing a high level of dopant).

According to the solid-state imaging device 2 of the second embodiment according to the present technology, it is possible to realize further improvement in quality and reliability of the solid-state imaging device. Specifically, according to the solid-state imaging device 2 of the second embodiment according to the present technology, as for the silicon (Si) layer 502 containing a high level of dopant, by introducing the silicon (Si) layer 502 containing a high level of dopant between a chip (for example, a chip forming the second semiconductor device 2-b or a chip forming the second semiconductor device 2-b and the third semiconductor device 2-c) and a wafer (a chip forming the first semiconductor device 2-a), rigidity increases, and for example, a thrust toward a photodiode (PD) side due to a difference in thermal expansion between an embedding material (insulating material) and wiring (metal material) decreases, an effect on an imaging characteristic decreases, and the silicon (Si) layer 502 containing a high level of dopant may absorb the light from outside, the hot carrier light emission (HC light emission) from the logic substrate (logic circuit), the leaking in incident light and the like to decrease the effect on the imaging characteristic. Moreover, as described above, according to the solid-state imaging device 2 of the second embodiment according to the present technology, the electromagnetic noise between the upper and lower substrates may be blocked by introducing the heavily doped silicon (Si) layer 502.

### 4. Third Embodiment (Example 3 of Solid-State Imaging Device)

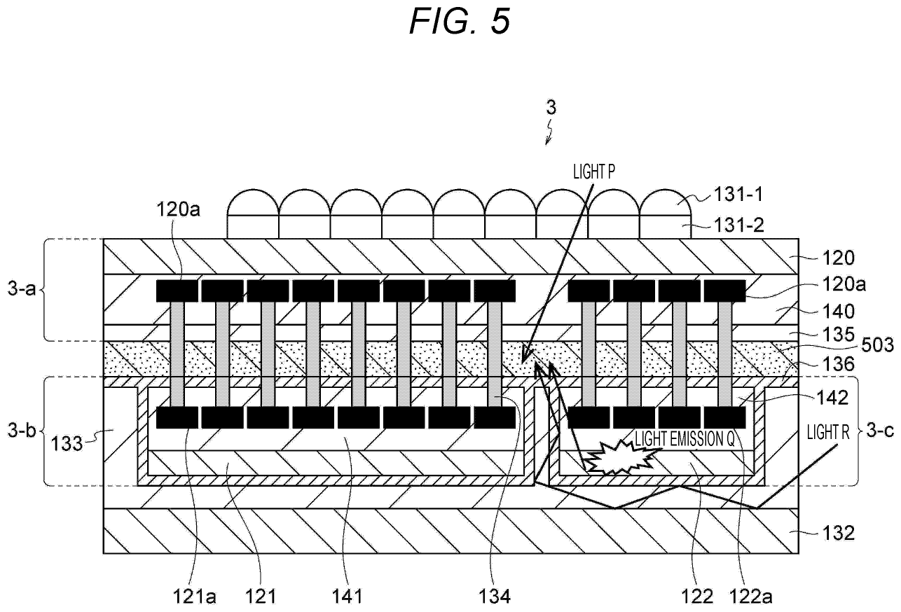

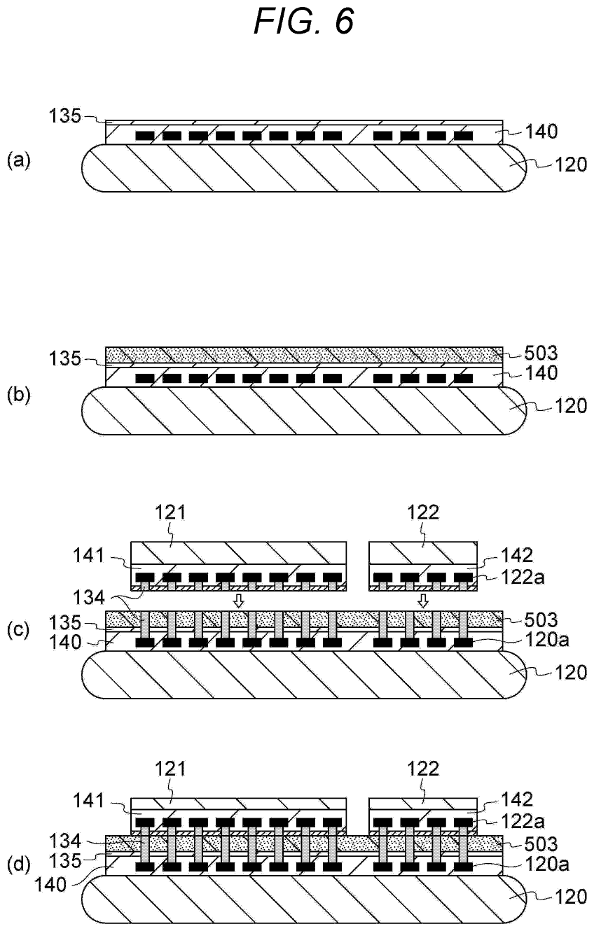

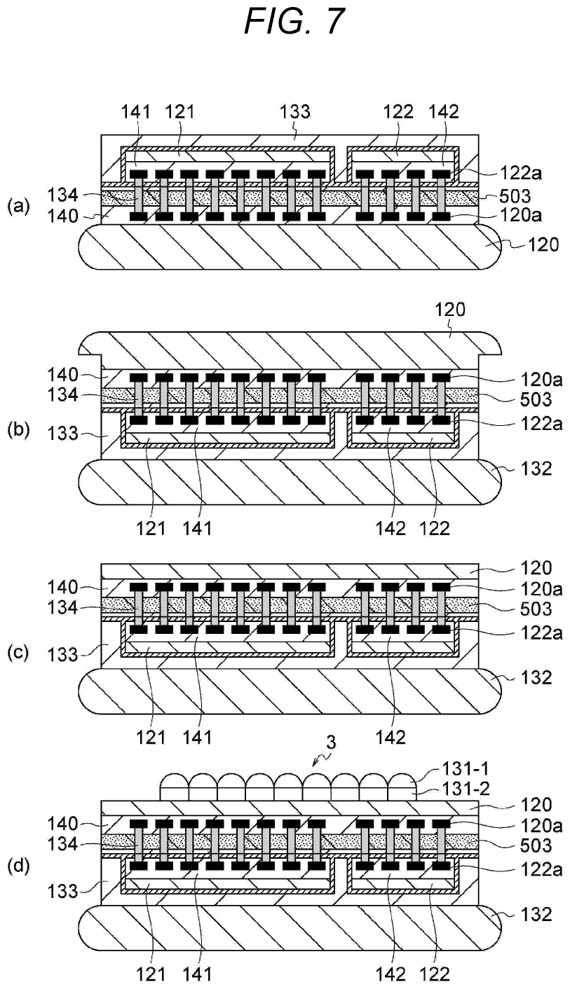

A solid-state imaging device of a third embodiment (example 3 of a solid-state imaging device) according to the present technology is described with reference to FIGS. 5 to 7. FIG. 5 is a cross-sectional view of a solid-state imaging device 3 of the third embodiment according to the present technology, and FIGS. 6 and 7 are cross-sectional views for illustrating a manufacturing method of the solid-state imaging device 3 of the third embodiment according to the present technology.

In the solid-state imaging device 3 illustrated in FIG. 5, an on-chip lens 131-1, an on-chip color filter 131-2, a solid-state imaging element 120, a wiring layer 140, an oxide film 135, and an amorphous silicon (Si) layer 503 are stacked in this order from an upper side (light incident side) in FIG. 5, and below them (lower side in FIG. 5), for example, a memory circuit 121 and a logic circuit 122 are stacked in substantially the same layer as signal processing circuits. The memory circuit 121 is arranged on a left side (left side in FIG. 5), and the logic circuit 122 is arranged on a right side (right side in FIG. 5). Then, in the solid-state imaging device 3 illustrated in FIG. 5, a support substrate 132 is formed below the memory circuit 121 and the logic circuit 122 (lower side in FIG. 5).

That is, as illustrated in FIG. 5, the solid-state imaging device 3 includes a first semiconductor device 3-a including the solid-state imaging element 120, the wiring layer 140, and the oxide film 135, a second semiconductor device 3-b including the memory circuit 121, a wiring layer 141, and an oxide film 136, and a third semiconductor device 3-c including the logic circuit 122, a wiring layer 142, and an oxide film 136, and a silicon containing layer (an amorphous silicon (Si) layer 503 in the third embodiment) is arranged (stacked) between the first semiconductor device 3-a and the second and third semiconductor devices 3-b and 3-c.

The amorphous silicon (Si) layer 503 may also have a structure not divided in a field angle of the solid-state imaging element 120 (image sensor) and is continuously formed across a plurality of pixels. A thickness of the amorphous silicon (Si) layer 503 may be any thickness, but is preferably 3 μm or more so that visible light may be absorbed. Furthermore, a relationship between the thickness of the amorphous silicon (Si) layer 503 (thickness A) and a thickness of the solid-state imaging element 120 (silicon (Si) substrate) (thickness B) preferably satisfies a relational expression A≥B.

As illustrated in FIG. 5, the amorphous silicon (Si) layer absorbs hot carrier light emission (HC light emission) (light emission Q in FIG. 5) occurring on a chip end face and a transistor forming a logic substrate, light from outside (light R in FIG. 5), and light leaking in from incident light transmitted through the solid-state imaging element (image sensor) 120 (light P in FIG. 5).

Out of terminals 120a formed in the wiring layer 140 of the solid-state imaging element 120, a terminal 120a on the memory circuit 121 is electrically connected to a terminal 121a formed in the wiring layer 141 of the memory circuit 121 by wiring 134 connected by Cu—Cu joint and including a through via that penetrates through the amorphous silicon (Si) layer 503.

Furthermore, out of terminals 120a formed in the wiring layer 140 of the solid-state imaging element 120, a terminal 120a on the logic circuit 122 is electrically connected to a terminal 122a formed in the wiring layer 142 of the logic circuit 122 by wiring 134 connected by Cu—Cu joint and including a through via that penetrates through the amorphous silicon (Si) layer 503.

A space around the semiconductor device 3-b and the semiconductor device 3-c in the second semiconductor device 3-b in which the memory circuit 121 and the wiring layer 141 are formed and the third semiconductor device 3-c in which the logic circuit 122 and the wiring layer 142 are formed is filled with an oxide film (insulating film) 133. Therefore, the semiconductor device 3-b and the semiconductor device 3-c are in a state of being embedded in the oxide film (insulating film) 133.

Furthermore, in a boundary region between the first semiconductor device 3-a and the second and third semiconductor devices 3-b and 3-c, the oxide film 135, the amorphous silicon (Si) layer 503, and the oxide film 136 are formed in this order from an upper side (light incident side) in FIG. 5. That is, the amorphous silicon (Si) layer 503 is formed at an interface of the Cu—Cu joint between the first semiconductor device 3-a and the second and third semiconductor devices 3-b and 3-c.

Moreover, the second and third semiconductor devices 3-b and 3-c are joined to the support substrate 132 via the oxide film (insulating film) 133 and an oxide film (not illustrated in FIG. 2; an oxide film between the oxide film 133 and the support substrate 132).

Next, a manufacturing method of the solid-state imaging device 3 is described with reference to FIGS. 6 and 7.

As illustrated in FIG. 6(a), in a back end of line (BEOL) process, the wiring layer 140 is formed on the solid-state imaging element (image sensor substrate) 120 and the oxide film 135 is formed on the wiring layer 140 to manufacture a first semiconductor device (the same as the first semiconductor device 3-a in FIG. 5).

The amorphous silicon (Si) layer 503 is formed on the first semiconductor device (oxide film 135) by using a chemical vapor deposition (CVD) method (FIG. 6 (b)).

In a case where copper (Cu) wiring is formed in the wiring layer 140, the amorphous silicon (Si) layer 503 is preferably deposited at 400° C. or lower by using the CVD method. As the silicon (Si) containing layer, in place of the amorphous silicon (Si) layer 503, a polycrystalline silicon (Si) layer may also be used, a single crystal silicon (Si) layer may also be used, or silicon (Si) of a combination arbitrarily selected from amorphous silicon (Si), polycrystalline silicon (Si), and single crystal silicon (Si) may also be used. A thickness of the amorphous silicon (Si) layer 503 may be any thickness, but is preferably 3 μm or more.

For the Cu—Cu joint, the wiring 134 including the through via that penetrates through the amorphous silicon (Si) layer 503 is formed for the terminal 120a, and as illustrated in FIG. 6(c), the first semiconductor device including the solid-state imaging element 120 and the like and diced second semiconductor device (memory chip) (the same as the second semiconductor device 3-b in FIG. 5) and third semiconductor device (logic chip) (the same as the third semiconductor device 3-c in FIG. 5) are joined by Cu—Cu joint by the wiring 134 by chip on wafer (CoW) to be electrically connected to each other. Note that, the terminal 121a and the wiring 134 connected to the terminal 121a are formed in advance in the second semiconductor device (memory chip), and the terminal 122a and the wiring 134 connected to the terminal 122a are formed in the third semiconductor device (logic chip).

As illustrated in FIG. 6(d), the silicon (Si) substrate forming the memory circuit 121 of the second semiconductor device (memory chip) and the silicon (Si) substrate forming the logic circuit 122 of the third semiconductor device (logic chip) are thinned.

This is described with reference to FIG. 7.

As illustrated in FIG. 7(a), a step in the second semiconductor device (memory chip) and the third semiconductor device (logic chip) is embedded and flattened. An inorganic material may be used, an organic material may be used, or a combination of both of them may be used for embedding and flattening the chip step. In FIG. 7(a), an embedding member is the oxide film (insulating film) 133.

As illustrated in FIG. 7(b), it is inverted such that the solid-state imaging element 120 in a lower portion illustrated in FIG. 7(a) (lower side in FIG. 7(a)) is located in an upper portion (upper side in FIG. 7(b)), the support substrate 132 is adhered to a lower portion of the oxide film 133 (lower side in FIG. 3(b)) via an oxide film (insulating film; not illustrated), and the silicon (Si) substrate forming the solid-state imaging element 120 is thinned to a predetermined thickness (FIG. 7(c)).

Finally, as illustrated in FIG. 7(d), a back surface light-shielding structure (not illustrated) is formed, the on-chip color filter 131-2 is formed on the solid-state imaging element 120, and the on-chip lens 131-1 is formed on the on-chip color filter 131-2. Then, by opening a pad (not illustrated), a device structure of the solid-state imaging device 3 is completed, and the solid-state imaging device 3 is manufactured.

According to the solid-state imaging device 3 of the third embodiment according to the present technology, it is possible to realize further improvement in quality and reliability of the solid-state imaging device. Specifically, according to the solid-state imaging device 3 of the third embodiment according to the present technology, as for the amorphous silicon (Si) layer 503, by introducing the amorphous silicon (Si) layer 503 between a chip (for example, a chip forming the second semiconductor device 3-b or a chip forming the second semiconductor device 3-b and the third semiconductor device 3-c) and a wafer (a chip forming the first semiconductor device 3-a), rigidity increases, and for example, a thrust toward a photodiode (PD) side due to a difference in thermal expansion between the embedding material (insulating material) and wiring (metal material) decreases, an effect on an imaging characteristic decreases, and the amorphous silicon (Si) layer 503 may absorb the light from outside, the hot carrier light emission (HC light emission) from the logic substrate (logic circuit), the leaking-in incident light and the like to decrease the effect on the imaging characteristic.

### 5. Fourth Embodiment (Example of Electronic Device)

An electronic device of a fourth embodiment according to the present technology is, as a first aspect, an electronic device equipped with a solid-state imaging device of a first aspect according to the present technology, and the solid-state imaging device of the first aspect according to the present technology is a solid-state imaging device provided with a first semiconductor device including an imaging element that generates a pixel signal on a pixel-by-pixel basis, a second semiconductor device in which a signal processing circuit required for signal processing of the pixel signal is embedded by an embedding member, and a silicon containing layer, in which the first semiconductor device and the second semiconductor device are electrically connected to each other, and the first semiconductor device, the silicon containing layer, and the second semiconductor device are arranged in this order.

Furthermore, the electronic device of the fourth embodiment according to the present technology is, as a second aspect, an electronic device equipped with a solid-state imaging device of a second aspect of the present technology, and the solid-state imaging device of the second aspect according to the present technology is a solid-state imaging device provided with a first semiconductor device including an imaging element that generates a pixel signal on a pixel-by-pixel basis, a second semiconductor device in which a first signal processing circuit required for signal processing of the pixel signal is embedded by an embedding member, a third semiconductor device in which a second signal processing circuit required for signal processing of the pixel signal is embedded by an embedding member, and a silicon containing layer, in which the first semiconductor device and the second semiconductor device are electrically connected to each other, the first semiconductor device and the third semiconductor device are electrically connected to each other, the first semiconductor device, the silicon containing layer, and the second semiconductor device are arranged in this order, and the first semiconductor device, the silicon containing layer, and the third semiconductor device are arranged in this order.

For example, the electronic device of the fourth embodiment according to the present technology is an electronic device equipped with the solid-state imaging device according to any one of the embodiments out of the solid-state imaging devices of the first to third embodiments according to the present technology.

### 6. Usage Example of Solid-State Imaging Device to Which Present Technology is Applied

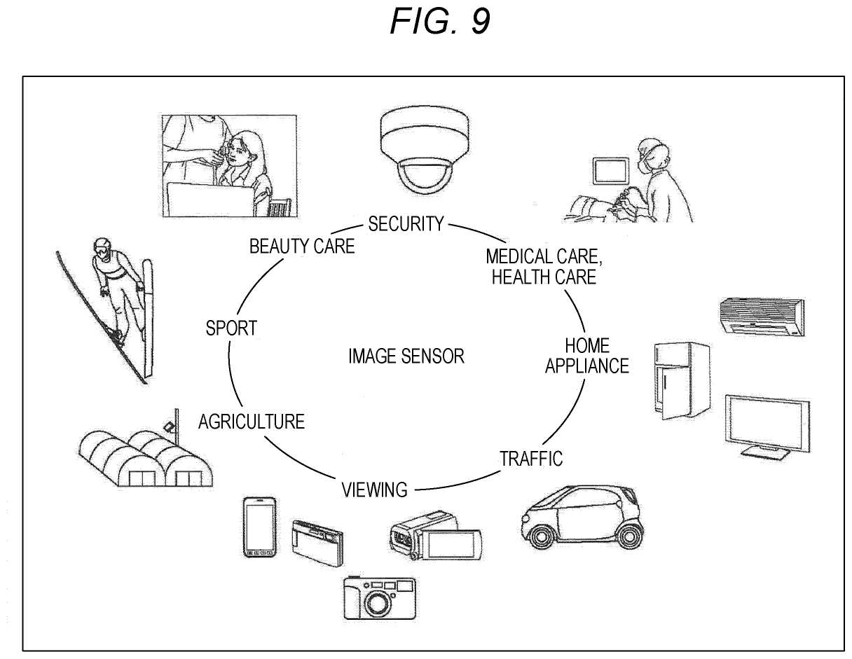

FIG. 9 is a view illustrating a usage example of the solid-state imaging device of the first to third embodiments according to the present technology as an image sensor.

The above-described solid-state imaging device of the first to third embodiments may be used in various cases in which light such as visible light, infrared light, ultraviolet light, and X-ray is sensed as described below, for example. That is, as illustrated in FIG. 9, for example, the solid-state imaging device of any one of the first to third embodiments may be used in a device (for example, the electronic device of the fourth embodiment described above) used in a viewing field in which an image to be viewed is taken, a traffic field, a home appliance field, a medical care and health care field, a security field, a beauty care field, a sport field, an agriculture field and the like.

Specifically, in the viewing field, for example, the solid-state imaging device of any one of the first to third embodiments may be used in a device for taking an image to be viewed such as a digital camera, a smartphone, and a mobile phone with a camera function.

In the traffic field, for example, the solid-state imaging device of any one of the first to third embodiments may be used in a device used for traffic such as an on-vehicle sensor that images the front, back, surroundings, inside and the like of an automobile, a monitoring camera that monitors running vehicles and roads, and a ranging sensor that measures a distance between vehicles and the like for safe driving such as automatic stop, recognition of a driver's condition and the like.

In the home appliance field, for example, the solid-state imaging device of any one of the first to third embodiments may be used in a device for home appliance such as a television receiver, a refrigerator, and an air conditioner for imaging a user's gesture and operating the device according to the gesture.

In the medical care and health care field, for example, the solid-state imaging device of any one of the first to third embodiments may be used in a device for medical care and health care such as an endoscope and a device performing angiography by receiving infrared light.

In the security field, for example, the solid-state imaging device of any one of the first to third embodiments may be used in a device for security such as a security monitoring camera and a personal authentication camera.

In the beauty care field, for example, the solid-state imaging device of any one of the first to third embodiments may be used in a device for beauty care such as a skin measuring device that images a skin and a microscope that images a head skin.

In the sport field, for example, the solid-state imaging device of any one of the first to third embodiments may be used in a device for sport such as an action camera and a wearable camera for sport and the like.

In the agriculture field, for example, the solid-state imaging device of any one of the first to third embodiments may be used in a device for agriculture such as a camera for monitoring a land and crop state.

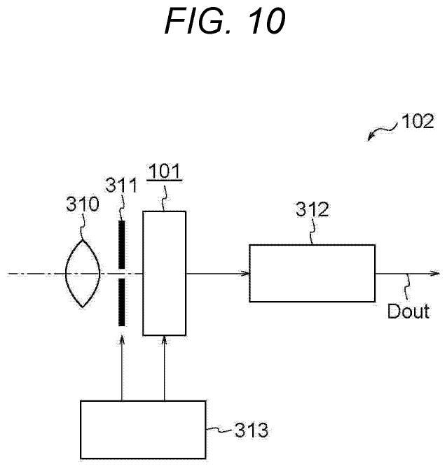

Next, the usage example of the solid-state imaging device of the first to third embodiments according to the present technology is specifically described. For example, the solid-state imaging device of any one of the first to third embodiments described above is applicable to any type of electronic device having an imaging function such as a camera system such as a digital still camera or a video camera, or a mobile phone having an imaging function, for example, as a solid-state imaging device 101. FIG. 10 illustrates a schematic configuration of an electronic device 102 (camera) as an example. The electronic device 102 is, for example, a video camera capable of taking a still image or a moving image, and includes the solid-state imaging device 101, an optical system (optical lens) 310, a shutter device 311, a drive unit 313 that drives the solid-state imaging device 101 and the shutter device 311, and a signal processing unit 312.

The optical system 310 guides image light (incident light) from a subject to a pixel unit 101a of the solid-state imaging device 101. The optical system 310 may include a plurality of optical lenses. The shutter device 311 controls a light irradiation period and a light shielding period regarding the solid-state imaging device 101. The drive unit 313 controls a transfer operation of the solid-state imaging device 101 and a shutter operation of the shutter device 311. The signal processing unit 312 performs various types of signal processing on a signal output from the solid-state imaging device 101. A video signal Dout after the signal processing is stored in a storage medium such as a memory or output to a monitor and the like.

### 7. Application Example to Endoscopic Surgery System

The present technology is applicable to various products. For example, the technology according to the present disclosure (the present technology) may be applied to an endoscopic surgery system.

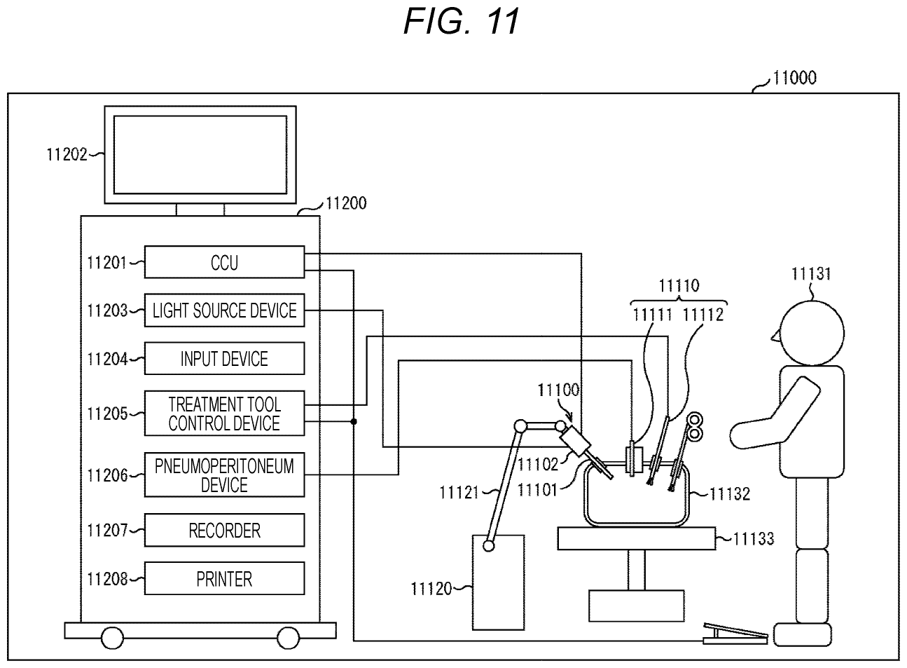

FIG. 11 is a view illustrating an example of a schematic configuration of the endoscopic surgery system to which the technology according to the present disclosure (present technology) is applicable.

FIG. 11 illustrates a state in which an operator (surgeon) 11131 performs surgery on a patient 11132 on a patient bed 11133 by using an endoscopic surgery system 11000. As illustrated, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens tube 11101 a region of a predetermined length from a distal end of which is inserted into a body cavity of the patient 11132 and a camera head 11102 connected to a proximal end of the lens tube 11101. In the illustrated example, the endoscope 11100 configured as a so-called rigid scope including a rigid lens tube 11101 is illustrated, but the endoscope 11100 may also be configured as a so-called flexible scope including a flexible lens tube.

At a distal end of the lens tube 11101, an opening into which an objective lens is fitted is provided. A light source device 11203 is connected to the endoscope 11100 and light generated by the light source device 11203 is guided to the distal end of the lens tube by a light guide extending inside the lens tube 11101, and applied to an observation target in the body cavity of the patient 11132 via the objective lens. Note that, the endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system.

The observation light is photoelectrically converted by the imaging element, and an electric signal corresponding to the observation light, that is, an image signal corresponding to an observation image is generated. The image signal is transmitted as RAW data to a camera control unit (CCU) 11201.

The CCU 11201 is configured by a central processing unit (CPU), a graphics processing unit (GPU) and the like, and comprehensively controls operation of the endoscope 11100 and a display device 11202. Moreover, the CCU 11201 receives the image signal from the camera head 11102 and applies various types of image processing for displaying an image based on the image signal, for example, development processing (demosaic processing) and the like on the image signal.

The display device 11202 displays the image based on the image signal subjected to the image processing by the CCU 11201 under the control of the CCU 11201.

The light source device 11203 includes a light source such as, for example, a light emitting diode (LED), and supplies the endoscope 11100 with irradiation light for imaging a surgical site and the like.

An input device 11204 is an input interface to the endoscopic surgery system 11000. A user may input various types of information and instructions to the endoscopic surgery system 11000 via the input device 11204. For example, the user inputs an instruction and the like to change an imaging condition (type of irradiation light, magnification, focal length and the like) by the endoscope 11100.

A treatment tool control device 11205 controls drive of the energy treatment tool 11112 for tissue cauterization, incision, blood vessel sealing or the like. A pneumoperitoneum device 11206 injects gas into the body cavity via the pneumoperitoneum tube 11111 to inflate the body cavity of the patient 11132 for the purpose of securing a visual field by the endoscope 11100 and securing a working space of the operator. A recorder 11207 is a device capable of recording various types of information regarding surgery. A printer 11208 is a device capable of printing various types of information regarding surgery in various formats such as text, image, or graph.

Note that, the light source device 11203 which supplies the irradiation light for imaging the surgical site to the endoscope 11100 may include, for example, an LED, a laser light source, or a white light source obtained by combining them. Since output intensity and output timing of each color (each wavelength) may be controlled with a high degree of accuracy in a case where the white light source is formed by the combination of RGB laser light sources, the light source device 11203 may adjust white balance of the taken image. Furthermore, in this case, by irradiating the observation target with the laser light from each of the RGB laser light sources in time division manner and controlling the drive of the imaging element of the camera head 11102 in synchronization with the irradiation timing, it is also possible to take images corresponding to RGB in time division manner. According to this method, a color image may be obtained without providing a color filter in the imaging element.

Furthermore, drive of the light source device 11203 may be controlled such that the intensity of light to be output is changed every predetermined time. By controlling drive of the imaging element of the camera head 11102 in synchronization with the timing of the change of the light intensity to obtain images in a time division manner and combining the images, an image of a high dynamic range without so-called black defect and halation may be generated.

Furthermore, the light source device 11203 may be configured to be able to supply light of a predetermined wavelength band corresponding to special light observation. In the special light observation, for example, by applying light of a narrower band than that of the irradiation light at ordinary observation (in other words, white light) by utilizing wavelength dependency of absorption of light in the body tissue, so-called narrow band imaging is performed in which predetermined tissue such as the blood vessel in the mucosal surface layer is imaged with high contrast. Alternatively, in the special light observation, fluorescent observation for obtaining an image by fluorescence generated by irradiation of excitation light may be performed. In the fluorescent observation, it is possible to irradiate the body tissue with excitation light to observe fluorescence from the body tissue (autonomous fluorescent observation) or to locally inject a reagent such as indocyanine green (ICG) to the body tissue and irradiate the body tissue with excitation light corresponding to a fluorescent wavelength of the reagent, thereby obtaining a fluorescent image, for example. The light source device 11203 may be configured to be able to supply the narrow band light and/or excitation light corresponding to such special light observation.

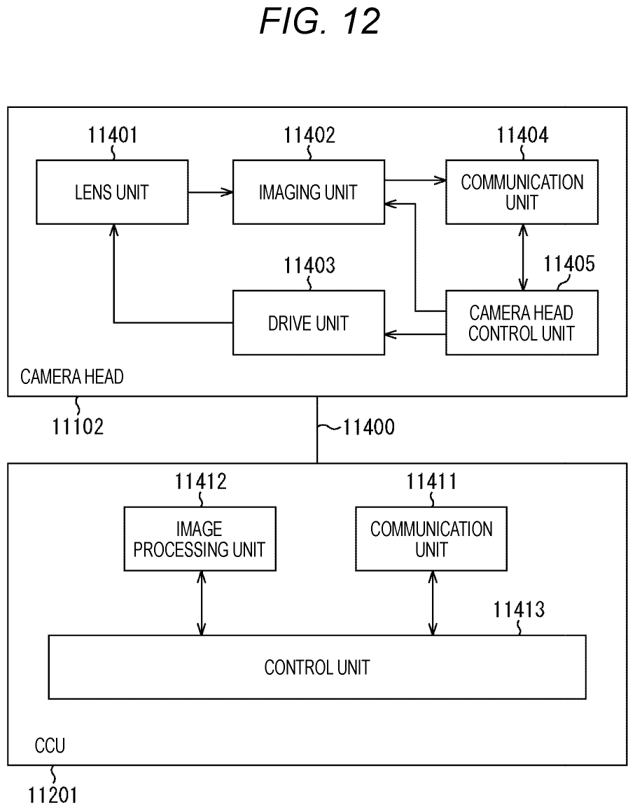

FIG. 12 is a block diagram illustrating an example of functional configurations of the camera head 11102 and the CCU 11201 illustrated in FIG. 11.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected to each other so as to be able to communicate by a transmission cable 11400.

The lens unit 11401 is an optical system provided at a connection to the lens tube 11101. The observation light taken in from the distal end of the lens tube 11101 is guided to the camera head 11102 and is incident on the lens unit 11401. The lens unit 11401 is configured by combining a plurality of lenses including a zoom lens and a focus lens.

The imaging unit 11402 includes an imaging element. The imaging element forming the imaging unit 11402 may be one imaging element (a so-called single plate type) or a plurality of imaging elements (a so-called multiple plate type). In a case where the imaging unit 11402 is of the multiple plate type, for example, the image signals corresponding to RGB may be generated by the respective imaging elements, and a color image may be obtained by combining them. Alternatively, the imaging unit 11402 may include a pair of imaging elements for obtaining right-eye and left-eye image signals corresponding to three-dimensional (3D) display. By the 3D display, the operator 11131 may grasp a depth of the living tissue in the surgical site more accurately. Note that, in a case where the imaging unit 11402 is of the multiple plate type, a plurality of systems of lens units 11401 may be provided so as to correspond to the respective imaging elements.

Furthermore, the imaging unit 11402 is not necessarily provided on the camera head 11102. For example, the imaging unit 11402 may be provided inside the lens tube 11101 immediately after the objective lens.

The drive unit 11403 includes an actuator and moves the zoom lens and the focus lens of the lens unit 11401 by a predetermined distance along an optical axis under the control of the camera head control unit 11405. Therefore, the magnification and focal point of the image taken by the imaging unit 11402 may be appropriately adjusted.

The communication unit 11404 includes a communication device for transmitting and receiving various types of information to and from the CCU 11201. The communication unit 11404 transmits the image signal obtained from the imaging unit 11402 as the RAW data to the CCU 11201 via the transmission cable 11400.

Furthermore, the communication unit 11404 receives a control signal for controlling drive of the camera head 11102 from the CCU 11201 and supplies the same to the camera head control unit 11405. The control signal includes, for example, information regarding imaging conditions such as information specifying a frame rate of the taken image, information specifying an exposure value at the time of imaging, and/or information specifying the magnification and focal point of the taken image.

Note that, the imaging conditions such as the above-described frame rate, exposure value, magnification, and focal point may be appropriately specified by the user or automatically set by the control unit 11413 of the CCU 11201 on the basis of the obtained image signal. In the latter case, the endoscope 11100 has a so-called auto exposure (AE) function, an auto focus (AF) function, and an auto white balance (AWB) function.

The camera head control unit 11405 controls the drive of the camera head 11102 on the basis of the control signal from the CCU 11201 received via the communication unit 11404.

The communication unit 11411 includes a communication device for transmitting and receiving various types of information to and from the camera head 11102. The communication unit 11411 receives the image signal transmitted from the camera head 11102 via the transmission cable 11400.

Furthermore, the communication unit 11411 transmits the control signal for controlling the drive of the camera head 11102 to the camera head 11102. The image signal and the control signal may be transmitted by electric communication, optical communication and the like.

The image processing unit 11412 performs various types of image processing on the image signal being the RAW data transmitted from the camera head 11102.

The control unit 11413 performs various types of control regarding imaging of the surgical site and the like by the endoscope 11100 and display of the taken image obtained by imaging the surgical site and the like. For example, the control unit 11413 generates the control signal for controlling the drive of the camera head 11102.

Furthermore, the control unit 11413 allows the display device 11202 to display the taken image of the surgical site and the like on the basis of the image signal subjected to the image processing by the image processing unit 11412. At that time, the control unit 11413 may recognize various objects in the taken image using various image recognition technologies. For example, the control unit 11413 may detect a shape, a color and the like of an edge of the object included in the taken image, thereby recognizing a surgical tool such as forceps, a specific living-body site, bleeding, mist when using the energy treatment tool 11112 and the like. When allowing the display device 11202 to display the taken image, the control unit 11413 may superimpose to display various types of surgery support information on the image of the surgical site using a recognition result. The surgery support information is superimposed to be displayed, and presented to the operator 11131, so that a burden on the operator 11131 may be reduced and the operator 11131 may reliably proceed with surgery.

The transmission cable 11400 connecting the camera head 11102 and the CCU 11201 is an electric signal cable supporting communication of electric signals, an optical fiber supporting optical communication, or a composite cable thereof.

Here, in the illustrated example, the communication is performed by wire using the transmission cable 11400, but the communication between the camera head 11102 and the CCU 11201 may be performed wirelessly.

An example of the endoscopic surgery system to which the technology according to the present disclosure may be applied is described above. The technology according to the present disclosure is applicable to the endoscope 11100, (the imaging unit 11402 of) the camera head 11102 and the like out of the configurations described above. Specifically, the solid-state imaging device 111 of the present technology may be applied to the imaging unit 10402. By applying the technology according to the present disclosure to the endoscope 11100, (the imaging unit 11402 of) the camera head 11102 and the like, the quality and reliability of the endoscope 11100, (the imaging unit 11402 of) the camera head 11102 and the like may be improved.

The endoscopic surgery system is herein described as an example, but in addition to this, the technology according to the present disclosure may also be applied to a microscopic surgery system and the like, for example.

### 8. Application Example to Mobile Body

The technology according to the present disclosure (present technology) may be applied to various products.

For example, the technology according to the present disclosure may also be realized as a device mounted on any type of mobile body such as an automobile, an electric automobile, a hybrid electric automobile, a motorcycle, a bicycle, a personal mobility, an airplane, a drone, a ship, and a robot.

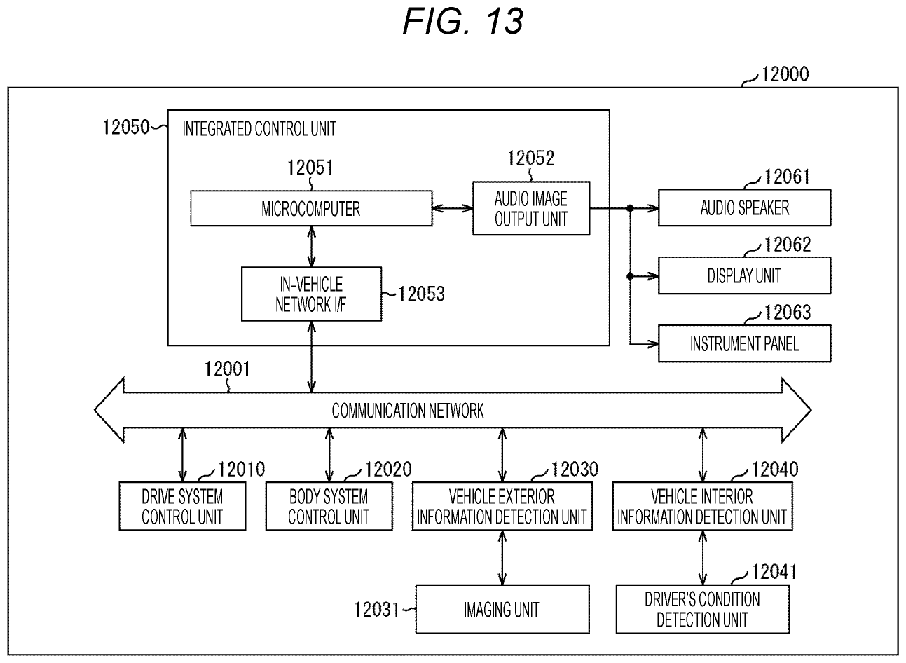

FIG. 13 is a block diagram illustrating a schematic configuration example of a vehicle control system being an example of a mobile body control system to which the technology according to the present disclosure is applicable.

A vehicle control system 12000 is provided with a plurality of electronic control units connected to one another via a communication network 12001. In the example illustrated in FIG. 13, the vehicle control system 12000 is provided with a drive system control unit 12010, a body system control unit 12020, a vehicle exterior information detection unit 12030, a vehicle interior information detection unit 12040, and an integrated control unit 12050. Furthermore, a microcomputer 12051, an audio image output unit 12052, and an in-vehicle network interface (I/F) 12053 are illustrated as functional configurations of the integrated control unit 12050.

The drive system control unit 12010 controls operation of devices related to a drive system of a vehicle according to various programs. For example, the drive system control unit 12010 serves as a control device of a driving force generating device for generating driving force of the vehicle such as an internal combustion engine or a driving motor, a driving force transmitting mechanism for transmitting the driving force to wheels, a steering mechanism for adjusting a rudder angle of the vehicle, a braking device for generating braking force of the vehicle and the like.

The body system control unit 12020 controls operation of various devices mounted on a vehicle body according to the various programs. For example, the body system control unit 12020 serves as a control device of a keyless entry system, a smart key system, a power window device, or various lights such as a head light, a backing light, a brake light, a blinker, or a fog light. In this case, a radio wave transmitted from a portable device that substitutes for a key or signals of various switches may be input to the body system control unit 12020. The body system control unit 12020 receives an input of the radio wave or signals and controls a door lock device, a power window device, the lights and the like of the vehicle.

The vehicle exterior information detection unit 12030 detects information outside the vehicle equipped with the vehicle control system 12000. For example, an imaging unit 12031 is connected to the vehicle exterior information detection unit 12030. The vehicle exterior information detection unit 12030 allows the imaging unit 12031 to take an image of the exterior of the vehicle and receives taken image data. The vehicle exterior information detection unit 12030 may perform detection processing of objects such as a person, a vehicle, an obstacle, a sign, or a character on a road surface or distance detection processing on the basis of the received image.

The imaging unit 12031 is an optical sensor that receives light and outputs an electric signal corresponding to an amount of the received light. The imaging unit 12031 may output the electric signal as the image or output the same as ranging information. Furthermore, the light received by the imaging unit 12031 may be visible light or invisible light such as infrared light.

The vehicle interior information detection unit 12040 detects information in the vehicle. The vehicle interior information detection unit 12040 is connected to, for example, a driver's condition detection unit 12041 for detecting a driver's condition. The driver's condition detection unit 12041 includes, for example, a camera that images the driver, and the vehicle interior information detection unit 12040 may calculate a driver's fatigue level or concentration level or may determine whether or not the driver is dozing on the basis of detection information input from the driver's condition detection unit 12041.

The microcomputer 12051 may calculate a control target value of the driving force generating device, the steering mechanism, or the braking device on the basis of the information inside and outside the vehicle obtained by the vehicle exterior information detection unit 12030 or the vehicle interior information detection unit 12040, and output a control instruction to the drive system control unit 12010. For example, the microcomputer 12051 may perform cooperative control for realizing functions of advanced driver assistance system (ADAS) including collision avoidance or impact attenuation of the vehicle, following travel based on the distance between the vehicles, vehicle speed maintaining travel, vehicle collision warning, vehicle lane departure warning and the like.

Furthermore, the microcomputer 12051 may perform the cooperative control for realizing automatic driving and the like to autonomously travel independent from the operation of the driver by controlling the driving force generating device, the steering mechanism, the braking device or the like on the basis of the information around the vehicle obtained by the vehicle exterior information detection unit 12030 or the vehicle interior information detection unit 12040.

Furthermore, the microcomputer 12051 may output the control instruction to the body system control unit 12020 on the basis of the information outside the vehicle obtained by the vehicle exterior information detection unit 12030. For example, the microcomputer 12051 may perform the cooperative control to realize glare protection such as controlling the head light according to a position of a preceding vehicle or an oncoming vehicle detected by the vehicle exterior information detection unit 12030 to switch a high beam to a low beam.

The audio image output unit 12052 transmits at least one of audio or image output signal to an output device capable of visually or audibly notifying an occupant of the vehicle or the outside the vehicle of the information. In the example in FIG. 13, as the output device, an audio speaker 12061, a display unit 12062, and an instrument panel 12063 are illustrated. The display unit 12062 may include at least one of an on-board display or a head-up display, for example.

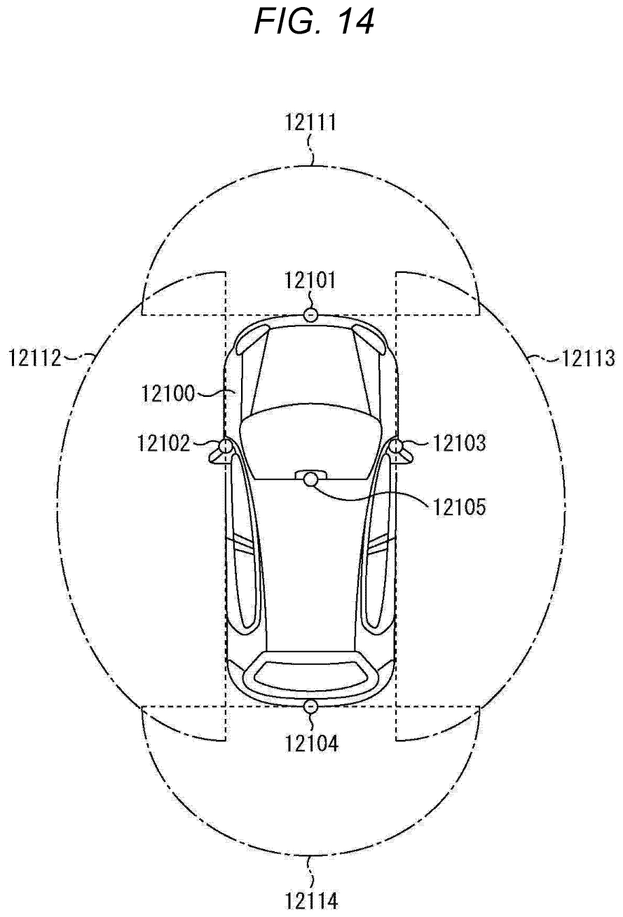

FIG. 14 is a view illustrating an example of an installation position of the imaging unit 12031.

In FIG. 14, the vehicle 12100 includes imaging units 12101, 12102, 12103, 12104, and 12105 as the imaging unit 12031.

The imaging units 12101, 12102, 12103, 12104, and 12105 are provided in positions such as, for example, a front nose, a side mirror, a rear bumper, a rear door, and an upper portion of a front windshield in a vehicle interior of the vehicle 12100. The imaging unit 12101 provided on the front nose and the imaging unit 12105 provided in the upper portion of the front windshield in the vehicle interior principally obtain images in front of the vehicle 12100. The imaging units 12102 and 12103 provided on the side mirrors principally obtain images of the sides of the vehicle 12100. The imaging unit 12104 provided on the rear bumper or the rear door principally obtains an image behind the vehicle 12100. The images in front obtained by the imaging units 12101 and 12105 are principally used for detecting a preceding vehicle, or a pedestrian, an obstacle, a traffic signal, a traffic sign, a lane or the like.

Note that, in FIG. 14, an example of imaging ranges of the imaging units 12101 to 12104 is illustrated. An imaging range 12111 indicates the imaging range of the imaging unit 12101 provided on the front nose, imaging ranges 12112 and 12113 indicate the imaging ranges of the imaging units 12102 and 12103 provided on the side mirrors, and an imaging range 12114 indicates the imaging range of the imaging unit 12104 provided on the rear bumper or the rear door. For example, image data taken by the imaging units 12101 to 12104 are superimposed, so that an overlooking image of the vehicle 12100 as seen from above is obtained.

At least one of the imaging units 12101 to 12104 may have a function of obtaining distance information. For example, at least one of the imaging units 12101 to 12104 may be a stereo camera including a plurality of imaging elements, or may be an imaging element including pixels for phase difference detection.

For example, the microcomputer 12051 may extract especially a closest solid object on a traveling path of the vehicle 12100, the solid object traveling at a predetermined speed (for example, 0 km/h or higher) in a direction substantially the same as that of the vehicle 12100 as the preceding vehicle by obtaining a distance to each solid object in the imaging ranges 12111 to 12114 and a change in time of the distance (relative speed relative to the vehicle 12100) on the basis of the distance information obtained from the imaging units 12101 to 12104. Moreover, the microcomputer 12051 may set the distance between the vehicles to be secured in advance from the preceding vehicle, and may perform automatic brake control (including following stop control), automatic acceleration control (including following start control) and the like. In this manner, it is possible to perform the cooperative control for realizing the automatic driving and the like to autonomously travel independent from the operation of the driver.

For example, the microcomputer 12051 may extract solid object data regarding the solid object while sorting the same into a motorcycle, a standard vehicle, a large-sized vehicle, a pedestrian, and other solid objects such as a utility pole on the basis of the distance information obtained from the imaging units 12101 to 12104 and use for automatically avoiding obstacles. For example, the microcomputer 12051 discriminates the obstacles around the vehicle 12100 into an obstacle visible to a driver of the vehicle 12100 and an obstacle difficult to see. Then, the microcomputer 12051 determines a collision risk indicating a degree of risk of collision with each obstacle, and when the collision risk is equal to or higher than a set value and there is a possibility of collision, this may perform driving assistance for avoiding the collision by outputting an alarm to the driver via the audio speaker 12061 and the display unit 12062 or performing forced deceleration or avoidance steering via the drive system control unit 12010.

At least one of the imaging units 12101 to 12104 may be an infrared camera for detecting infrared rays. For example, the microcomputer 12051 may recognize a pedestrian by determining whether or not there is a pedestrian in the images taken by the imaging units 12101 to 12104. Such pedestrian recognition is carried out, for example, by a procedure of extracting feature points in the images taken by the imaging units 12101 to 12104 as the infrared cameras and a procedure of performing pattern matching processing on a series of feature points indicating an outline of an object to discriminate whether or not this is a pedestrian. When the microcomputer 12051 determines that there is a pedestrian in the images taken by the imaging units 12101 to 12104 and recognizes the pedestrian, the audio image output unit 12052 controls the display unit 12062 to superimpose a rectangular contour for emphasis on the recognized pedestrian to display. Furthermore, the audio image output unit 12052 may control the display unit 12062 to display an icon and the like indicating the pedestrian at a desired position.

An example of the vehicle control system to which the technology according to the present disclosure (present technology) is applicable is described above. The technology according to the present disclosure is applicable to the imaging unit 12031 and the like, for example, out of the configurations described above. Specifically, the solid-state imaging device 111 of the present disclosure may be applied to the imaging unit 12031. By applying the technology according to the present disclosure to the imaging unit 12031, it is possible to improve the quality and reliability of the imaging unit 12031.

Note that, the present technology is not limited to the above-described embodiments and application examples and various modifications may be made without departing from the gist of the present technology.

Furthermore, the effect described in this specification is illustrative only; the effect is not limited thereto and there may also be another effect.

Furthermore, the present technology may also have the following configuration.

[1]

A solid-state imaging device provided with:

a first semiconductor device including an imaging element that generates a pixel signal on a pixel-by-pixel basis;

a second semiconductor device in which a signal processing circuit required for signal processing of the pixel signal is embedded by an embedding member; and

a silicon containing layer,

in which the first semiconductor device and the second semiconductor device are electrically connected to each other, and

the first semiconductor device, the silicon containing layer, and the second semiconductor device are arranged in this order.

[2]

The solid-state imaging device according to [1],

in which a through via that penetrates through the silicon containing layer is formed, and the first semiconductor device and the second semiconductor device are electrically connected to each other via the through via.

[3]

The solid-state imaging device according to [1] or [2],

in which the first semiconductor device and the second semiconductor device are electrically connected to each other by Cu—Cu joint.

[4]

The solid-state imaging device according to [1] or [2],

in which the first semiconductor device and the second semiconductor device are electrically connected to each other by Cu—Cu joint, and

the silicon containing layer is formed at an interface of the Cu—Cu joint between the first semiconductor device and the second semiconductor device.

[5]

The solid-state imaging device according to any one of [1] to [4],

in which a through via that penetrates through the silicon containing layer is formed, and the first semiconductor device and the second semiconductor device are electrically connected to each other by Cu—Cu joint via the through via.

[6]

The solid-state imaging device according to any one of [1] to [5],

in which the silicon containing layer is continuously formed across a plurality of the pixels.

[7]

The solid-state imaging device according to any one of [1] to [6],

in which the silicon containing layer contains at least one type of silicon selected from a group consisting of single crystal silicon, amorphous silicon, and polycrystalline silicon.

[8]

The solid-state imaging device according to any one of [1] to [7],

in which the silicon containing layer contains dopant.

[9]

The solid-state imaging device according to [8],

in which a content of the dopant in the silicon containing layer is 1E18 atoms/cm³ or more.

[10]

A solid-state imaging device provided with:

a first semiconductor device including an imaging element that generates a pixel signal on a pixel-by-pixel basis;

a second semiconductor device in which a first signal processing circuit required for signal processing of the pixel signal is embedded by an embedding member;

a third semiconductor device in which a second signal processing circuit required for signal processing of the pixel signal is embedded by an embedding member; and

a silicon containing layer,

in which the first semiconductor device and the second semiconductor device are electrically connected to each other,

the first semiconductor device and the third semiconductor device are electrically connected to each other,

the first semiconductor device, the silicon containing layer, and the second semiconductor device are arranged in this order, and

the first semiconductor device, the silicon containing layer, and the third semiconductor device are arranged in this order.

[11]

The solid-state imaging device according to [10],

in which the second semiconductor device and the third semiconductor device are formed in substantially the same layer.

[12]

The solid-state imaging device according to [10] or [11],

in which a first through via and a second through via that penetrate through the silicon containing layer are formed,

the first semiconductor device and the second semiconductor device are electrically connected to each other via the first through via, and

the first semiconductor device and the third semiconductor device are electrically connected to each other via the second through via.

[13]

The solid-state imaging device according to any one of [10] to [12],

in which the first semiconductor device and the second semiconductor device are electrically connected to each other by Cu—Cu joint, and

the first semiconductor device and the third semiconductor device are electrically connected to each other by Cu—Cu joint.

[14]

The solid-state imaging device according to any one of [10] to [13],

in which the first semiconductor device and the second semiconductor device are electrically connected to each other by Cu—Cu joint,

the first semiconductor device and the third semiconductor device are electrically connected to each other by Cu—Cu joint, and

the silicon containing layer is formed at an interface of the Cu—Cu joint between the first semiconductor device and the second and third semiconductor devices.

[15]

The solid-state imaging device according to any one of [10] to [14],

in which a first through via and a second through via that penetrate through the silicon containing layer are formed,

the first semiconductor device and the second semiconductor device are electrically connected to each other by Cu—Cu joint via the first through via, and

the first semiconductor device and the third semiconductor device are electrically connected to each other by Cu—Cu joint via the second through via.

[16]

The solid-state imaging device according to any one of [10] to [15],

in which the silicon containing layer is continuously formed across a plurality of the pixels.

[17]

The solid-state imaging device according to any one of [10] to [16],

in which the silicon containing layer contains at least one type of silicon selected from a group consisting of single crystal silicon, amorphous silicon, and polycrystalline silicon.

[18]

The solid-state imaging device according to any one of [10] to [17],

in which the silicon containing layer contains dopant.

[19]

The solid-state imaging device according to [18],

in which a content of the dopant in the silicon containing layer is 1E18 atoms/cm³ or more.

[20]

An electronic device equipped with a solid-state imaging device,

the solid-state imaging device provided with:

a first semiconductor device including an imaging element that generates a pixel signal on a pixel-by-pixel basis;

a second semiconductor device in which a signal processing circuit required for signal processing of the pixel signal is embedded by an embedding member; and

a silicon containing layer,

in which the first semiconductor device and the second semiconductor device are electrically connected to each other, and

the first semiconductor device, the silicon containing layer, and the second semiconductor device are arranged in this order.

[21]

An electronic device equipped with a solid-state imaging device,

the solid-state imaging device provided with:

a first semiconductor device including an imaging element that generates a pixel signal on a pixel-by-pixel basis;

a second semiconductor device in which a first signal processing circuit required for signal processing of the pixel signal is embedded by an embedding member;

a third semiconductor device in which a second signal processing circuit required for signal processing of the pixel signal is embedded by an embedding member; and

a silicon containing layer,

in which the first semiconductor device and the second semiconductor device are electrically connected to each other,

the first semiconductor device and the third semiconductor device are electrically connected to each other,

the first semiconductor device, the silicon containing layer, and the second semiconductor device are arranged in this order, and

the first semiconductor device, the silicon containing layer, and the third semiconductor device are arranged in this order.

An electronic device equipped with the solid-state imaging device according to any one of [1] to [19].

### REFERENCE SIGNS LIST

1, 2, 3, 111 Solid-state imaging device
1-a, 2-a, 3-a First semiconductor device
1-b, 2-b, 3-b Second semiconductor device
1-a, 1-b, 1-c Third semiconductor device
501 Silicon (Si) layer
502 Silicon (Si) layer containing high level of dopant
503 Amorphous silicon (Si) layer

1. A solid-state imaging device comprising:
a first semiconductor device including an imaging element that generates a pixel signal on a pixel-by-pixel basis;
a second semiconductor device in which a signal processing circuit required for signal processing of the pixel signal is embedded by an embedding member; and
a silicon containing layer,
wherein the first semiconductor device and the second semiconductor device are electrically connected to each other, and
the first semiconductor device, the silicon containing layer, and the second semiconductor device are arranged in this order.

2. The solid-state imaging device according to claim 1,
wherein a through via that penetrates through the silicon containing layer is formed, and the first semiconductor device and the second semiconductor device are electrically connected to each other via the through via.

3. The solid-state imaging device according to claim 1,
wherein the first semiconductor device and the second semiconductor device are electrically connected to each other by Cu—Cu joint.

4. The solid-state imaging device according to claim 1,
wherein the first semiconductor device and the second semiconductor device are electrically connected to each other by Cu—Cu joint, and
the silicon containing layer is formed at an interface of the Cu—Cu joint between the first semiconductor device and the second semiconductor device.

5. The solid-state imaging device according to claim 1,
wherein a through via that penetrates through the silicon containing layer is formed, and the first semiconductor device and the second semiconductor device are electrically connected to each other by Cu—Cu joint via the through via.

6. The solid-state imaging device according to claim 1,
wherein the silicon containing layer is continuously formed across a plurality of the pixels.

7. The solid-state imaging device according to claim 1,
wherein the silicon containing layer contains at least one type of silicon selected from a group consisting of single crystal silicon, amorphous silicon, and polycrystalline silicon.

8. The solid-state imaging device according to claim 1,
wherein the silicon containing layer contains dopant.

9. The solid-state imaging device according to claim 8,
wherein a content of the dopant in the silicon containing layer is 1E18 atoms/cm³ or more.

10. A solid-state imaging device comprising:
a first semiconductor device including an imaging element that generates a pixel signal on a pixel-by-pixel basis;
a second semiconductor device in which a first signal processing circuit required for signal processing of the pixel signal is embedded by an embedding member;
a third semiconductor device in which a second signal processing circuit required for signal processing of the pixel signal is embedded by an embedding member; and
a silicon containing layer,
wherein the first semiconductor device and the second semiconductor device are electrically connected to each other,
the first semiconductor device and the third semiconductor device are electrically connected to each other,
the first semiconductor device, the silicon containing layer, and the second semiconductor device are arranged in this order, and
the first semiconductor device, the silicon containing layer, and the third semiconductor device are arranged in this order.

11. The solid-state imaging device according to claim 10,
wherein the second semiconductor device and the third semiconductor device are formed in substantially the same layer.

12. The solid-state imaging device according to claim 10,
wherein a first through via and a second through via that penetrate through the silicon containing layer are formed,
the first semiconductor device and the second semiconductor device are electrically connected to each other via the first through via, and
the first semiconductor device and the third semiconductor device are electrically connected to each other via the second through via.

13. The solid-state imaging device according to claim 10,
wherein the first semiconductor device and the second semiconductor device are electrically connected to each other by Cu—Cu joint, and
the first semiconductor device and the third semiconductor device are electrically connected to each other by Cu—Cu joint.

14. The solid-state imaging device according to claim 10,
wherein the first semiconductor device and the second semiconductor device are electrically connected to each other by Cu—Cu joint,
the first semiconductor device and the third semiconductor device are electrically connected to each other by Cu—Cu joint, and
the silicon containing layer is formed at an interface of the Cu—Cu joint between the first semiconductor device and the second and third semiconductor devices.

15. The solid-state imaging device according to claim 10,
wherein a first through via and a second through via that penetrate through the silicon containing layer are formed,
the first semiconductor device and the second semiconductor device are electrically connected to each other by Cu—Cu joint via the first through via, and
the first semiconductor device and the third semiconductor device are electrically connected to each other by Cu—Cu joint via the second through via.

16. The solid-state imaging device according to claim 10,
wherein the silicon containing layer is continuously formed across a plurality of the pixels.

17. The solid-state imaging device according to claim 10,
wherein the silicon containing layer contains at least one type of silicon selected from a group consisting of single crystal silicon, amorphous silicon, and polycrystalline silicon.

18. The solid-state imaging device according to claim 10,
wherein the silicon containing layer contains dopant.

19. The solid-state imaging device according to claim 18,
wherein a content of the dopant in the silicon containing layer is 1E18 atoms/cm³ or more.

20. An electronic device equipped with a solid-state imaging device,
the solid-state imaging device provided with:
a first semiconductor device including an imaging element that generates a pixel signal on a pixel-by-pixel basis;
a second semiconductor device in which a signal processing circuit required for signal processing of the pixel signal is embedded by an embedding member; and
a silicon containing layer,
wherein the first semiconductor device and the second semiconductor device are electrically connected to each other, and
the first semiconductor device, the silicon containing layer, and the second semiconductor device are arranged in this order.
